(19) United States
(12) Patent Application Publication
(10) Pub. No.: US 2009/0133249 A1
(43) Pub. Date: May 28, 2009

(54) METHOD AND APPARATUS FOR EVALUATING A COMPONENT PICK ACTION IN AN ELECTRONICS ASSEMBLY MACHINE

(75) Inventors: Steven K. Case, St. Louis Park, MN (US); John P. Konicek, Minneapolis, MN (US); David W. Duquette, Minneapolis, MN (US); Eric P. Rudd, Hopkins, MN (US); Swaminathan Manickam, Wilmington, MA (US)

Correspondence Address: WESTMAN CHAMPLIN & KELLY, P.A., SUITE 1400, 900 SECOND AVENUE SOUTH, MINNEAPOLIS, MN, 55402, US

(73) Assignee: CyberOptics Corporation, Golden Valley, MN (US)

(21) Appl. No.: 12/364,000

(22) Filed: Feb. 2, 2009

Related U.S. Application Data
(62) Division of application No. 11/436,389, filed on May 18, 2006.
Application No. 11/436,389 is a continuation-in-part of application No. 11/243,523, filed on Oct. 4, 2005.
(60) Provisional application No. 60/682,450, filed on May 19, 2005.

(51) Int. Cl. H05K 13/04; H04N 7/18

(52) U.S. Cl. 29/740; 29/743; 700/259; 348/87; 348/E07.085

(57) ABSTRACT

An electronics assembly apparatus with improved pick evaluation is provided. The apparatus includes a placement head having at least one nozzle for releasably picking up and holding a component. A robotic system is provided for generating relative movement between the placement head and a workpiece, such as a circuit board. An image acquisition system is disposed to obtain at least one before-pick image of a component pick up location and at least one after-pick image of the component pick up location. The before-pick image contains a plurality of image portions, having each image portion view the pick-up location from a different point of view, while the after-pick image contains a plurality of image portions, having each image portion view the pick-up location from a different point of view.

### CROSS-REFERENCE TO RELATED APPLICATION

The present application is a divisional application of U.S. patent application Ser. No. 11/436,389, filed May 18, 2006; which is based on and claims the benefit of U.S. provisional patent application Ser. No. 60/682,450, filed May 19, 2005; and is a Continuation-In-Part application of U.S. patent application Ser. No. 11/243,523, filed Oct. 4, 2005, entitled PICK AND PLACE MACHINE WITH IMPROVED COMPONENT PICK UP INSPECTION.

### COPYRIGHT RESERVATION

A portion of the disclosure of this patent document contains material which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### BACKGROUND OF THE INVENTION

Pick and place machines are generally used to manufacture electronic circuit boards. A blank printed circuit board is usually supplied to the pick and place machine, which then picks electronic components from component feeders, and places such components upon the board. The components are held upon the board temporarily by solder paste or adhesive until a subsequent step in which the solder paste is melted, or the adhesive is fully cured.

Pick and place machine operation is challenging. Since machine speed corresponds with throughput, the faster the pick and place machine runs, the less costly the manufactured board. Additionally, placement accuracy is extremely important. Many electrical components, such as chip capacitors and chip resistors are relatively small and must be accurately placed on equally small placement locations. Other components, while larger, have a significant number of leads or conductors that are spaced from one another at a relatively fine pitch. Such components must also be accurately placed to ensure that each lead is placed upon the proper pad. Thus, not only must the machine operate extremely fast, but it must also place components extremely accurately.

In order to enhance the quality of board manufacture, fully or partially populated boards are generally inspected after the placement operation(s), both before and after solder reflow, in order to identify components that are improperly placed or missing or any of a variety of errors that may occur. Automatic systems that perform such operation(s) are highly useful in that they help identify component placement problems prior to solder reflow allowing substantially easier rework or identify defective boards after reflow that are candidates for rework. One example of such a system is sold under the trade designation Model KS Flex available from CyberOptics Corporation of Golden Valley, Minnesota. This system can be used to identify such problems as alignment and rotation errors; missing and flipped components; billboards, where the part lays improperly on its longer side edge; tombstones, where the part lays improperly on its shorter edge; partial billboards and tombstones, where the part is oriented between its normal orientation and a billboard or tombstone orientation; component defects; incorrect polarity; and wrong components. Identification of errors pre-reflow provides a number of advantages. Rework is easier; closed-loop manufacturing control is facilitated; and less work in-process exists between error generation and remedy. While such systems provide highly useful inspection, they do consume plant floor-space as well as programming time, maintenance efforts and the like.

One relatively recent attempt to provide the benefits of after-placement inspection located within a pick a place machine itself is disclosed in U.S. Pat. No. 6,317,972 to Asai et al. That reference reports a method for mounting electric components where an image of a mounting location is obtained prior to component placement, and compared with an image of the mounting location after component placement to inspect the placement operation at the component level. While the disclosure of Asai et al. marks one attempt to employ in-machine component level inspection to inspect the component placement operation, component orientation errors can also be generated in the process of picking up a component. This process remains a challenge and a major contributor to the quality of the overall operation of the pick and place machine.

Picking up a component requires the placement head to be positioned over the pick up point for the target component. Once the nozzle is positioned, it is lowered to a point just above the component and, typically, a vacuum is applied through the nozzle which sucks the component up and temporarily attaches it to the end of the nozzle. Each component is positioned at its pick point by a component feeder mechanism. Typical feeder mechanisms include tape feeders, vibratory feeders and tray feeders. When required to configure a pick and place machine to assemble a new workpiece, an operator will insert the component feeders into their positions following an ordering scheme determined by the pick and place machine's program. Additionally, identification marks, such as barcodes, may be located on the feeder mechanisms to ensure the proper feeder is located in the proper position and sequence in the pick and place machine. Once a component is picked up by the nozzle, the feeder mechanism must move another component into the pick position.

If the component pick operation is not successful, defective workpieces are produced. Defects on workpieces that are known to be caused by bad pick operations are tombstoned components, missing components, wrong components, wrong component polarity, and misplaced components. Bad pick events can be caused by operators loading feeders into incorrect positions or allowing feeders to run out of components; defective or broken feeders, component tapes and nozzles; incorrectly programmed nozzle pick heights; or inconsistency in the normal pick process that result in components picked and held on the nozzle in a tombstone orientation, billboard orientation, or corner orientation, where the component is in contact with the nozzle at one of its corners. Any of these will lead to incorrectly positioned components.

### SUMMARY

An electronics assembly apparatus with improved pick evaluation is provided. The apparatus includes a placement head having at least one nozzle for releasably picking up and holding a component. A robotic system is provided for generating relative movement between the placement head and a workpiece, such as a circuit board. An image acquisition system is disposed to obtain at least one before-pick image of a component pick up location and at least one after-pick image of the component pick up location. The before-pick image contains a plurality of image portions, having each image portion view the pick-up location from a different point of view, while the after-pick image contains a plurality of image portions, having each image portion view the pick-up location from a different point of view.

### BRIEF DESCRIPTION OF THE DRAWINGS

FIG. 1 is a diagrammatic view of a Cartesian pick and place machine with which embodiments of the invention can be practiced.

FIG. 2 is a diagrammatic plan view of a turret pick and place machine with which embodiments of the invention can be practiced.

FIG. 3 is simplified diagrammatic view of an image acquisition system aligned with a pick up point of a component placement machine.

FIG. 4 is a diagrammatic view of image acquisition system disposed to acquire one or more images relative to a pick operation in accordance with an embodiment of the present invention.

FIG. 5 is a top plan view of a system illustrated diagrammatically in FIG. 4, with nozzle the eliminated for ease of illustration.

FIG. 6 is a diagrammatic view of an exemplary three-point of view before-pick image acquired in accordance with an embodiment of the present invention.

FIG. 7 is a diagrammatic exemplary view of the three-point of view embodiment illustrated in FIG. 6, acquired after a pick operation.

FIG. 8 is a flow diagram of a method for acquiring multiple sets of images relative to a pick operation in an electronics assembly machine.

### DETAILED DESCRIPTION OF ILLUSTRATIVE EMBODIMENTS

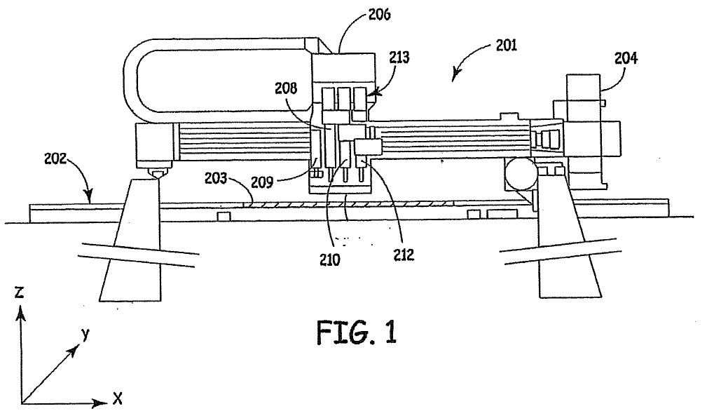

FIG. 1 is a diagrammatic view of an exemplary Cartesian pick and place machine 201 with which embodiments of the present invention are applicable. Pick and place machine 201 receives a workpiece, such as circuit board 203, via transport system or conveyor 202. A placement head 206 then obtains one or more electrical components to be mounted upon workpiece 203 from component feeders (not shown) and moves in x, y and z directions to place the component in the proper orientation at the proper location upon workpiece 203. Placement head 206 may include multiple nozzles 208, 210, 212 to pick multiple components. Some pick and place machines may employ a placement head that moves over a stationary camera to image the component(s) in order to ascertain component location and orientation upon each nozzle. The placement head 206 may also include a downwardly looking camera 209, which is generally used to locate fiducial marks upon workpiece 203 such that the relative location of placement head 206 with respect to workpiece 203 can be readily calculated.

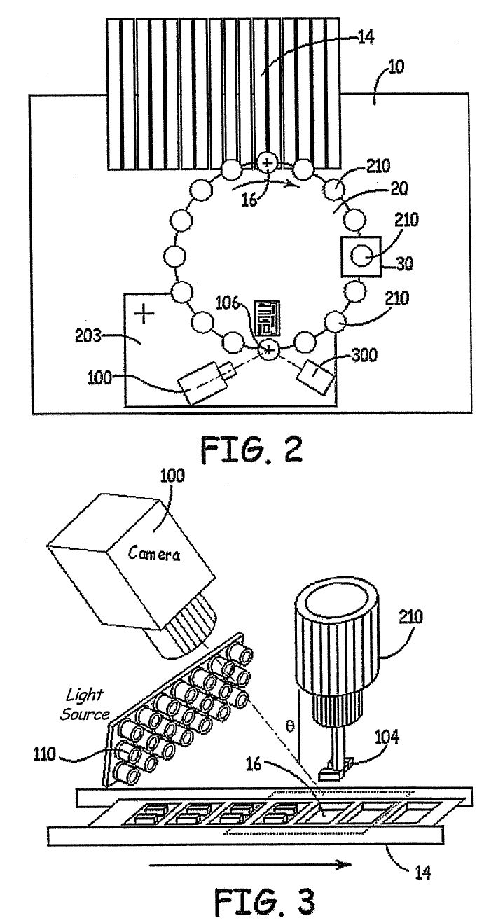

FIG. 2 is a diagrammatic view of an exemplary rotary turret pick and place machine 10 with which embodiments of the present invention are also applicable. Machine 10 includes some components that are similar to machine 201 and like components are numbered similarly. For turret pick and place machine 10, workpiece 203 is loaded via a conveyor onto an x-y stage (not shown). Attached to main turret 20 are nozzles 210 that are disposed at regular angular intervals around the rotating turret. During each pick and placement cycle, turret 20 indexes an angular distance equal to the angular distance between adjacent placement nozzles 210. After turret 20 rotates into position and workpiece 203 is positioned by the x-y stage, a placement nozzle 210 obtains a component 304 (shown in FIG. 3) from a component feeder 14 at a defined pick point 16. During this same interval, another nozzle 210 places a component 304 onto the workpiece 203 at a preprogrammed placement location 106. Additionally, while turret 20 pauses for the pick and place operation, upward looking camera 30 acquires and image of another component 304, which provides alignment information for that component. This alignment information is used by pick and place machine 10 to position workpiece 203 when placement nozzle 210 is positioned several steps later to place component 104. After the pick and place cycle is complete, turret 20 indexes to the next angular position and workpiece 203 is repositioned in x-y direction(s) to move the placement location to position which corresponds to the placement location 106.

FIG. 3 is a diagrammatic view of a placement head in accordance with embodiments of the present invention. FIG. 3 illustrates image acquisition system 300 disposed to acquire images of pick up location 16 of component 304 before and after component 304 is picked up by nozzle 210 from location 16 in feeder 14. Device 300 obtains images of pick up location 16 on feeder 14 prior to pick up of component 304 and then shortly thereafter. A comparison of these before and after images facilitates component-level pick up inspection and verification. In addition, the area surrounding the component pick up location 16 is also imaged. Since acquisition of images of the pick up location 16 is generally done when nozzle 210 is located above the pick up location 16, it is important to be able to image pick up location 16 while minimizing or reducing interference from component 304 itself or parts of placement nozzle 210. Thus, it is preferred that system 300 employ an optical axis allowing views that are inclined at an angle θ with respect to the axis of nozzle 210. An additional advantage of having system 300 inclined at an angle θ is that vertical motion of component 304, feeder, and component holding tape/tray can be detected and measured by determining the translation of these items between image acquisitions. It is also helpful to precisely time the image acquisition interval such that the pick up location 16 and the placement head 210 are relatively aligned with each other and that component 304 is visible in the feeder 14 from the camera angle. After component 304 is picked up, the second image should be timed such that it is at a pre-selected time during the pick up cycle. A method to precisely time the acquisitions of these two images is described in a co-pending application Ser. No. (10/970,355).

Embodiments of the present invention generally obtain two or more sets of successive images of the intended pick up location (i.e. before pick up and after). Since pick up occurs relatively quickly, and since slowing machine throughput is extremely undesirable, it is sometimes necessary to acquire two successive images very quickly since cessation of the relative motion between the placement head and the pick up position is fleeting. For example, it may be necessary to acquire two images within a period of approximately 10 milliseconds.

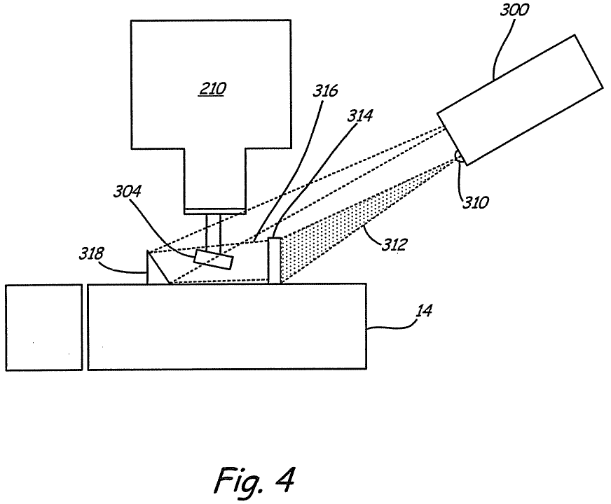

FIG. 4 is a diagrammatic view of image acquisition system 300 disposed to acquire one or more images relative to a pick operation in accordance with an embodiment of the present invention. Image acquisition system 300 preferably includes an electronic camera (CCD, CMOS, or other) that is disposed to view component 304 when component 304 is held by nozzle 210. Preferably, image acquisition system 300 is disposed to have an optical axis such that it views component 304 from a non-zero angle with respect to horizontal. System 300 also preferably includes an illuminator 310 that generates illumination 312, which illumination 312 is redirected by illumination optics 314. Redirected illumination 316 passes through the area proximate component 304 when component 304 is retained on nozzle 210. Imaging optics 318 is disposed to redirect and focus the illumination upon image acquisition system 300. The utilization of illumination optics 314 and imaging optics 318 allows image acquisition system 300 to obtain a backlit side elevation view of component 304, even though component 304 is maintained at an angle that is different than the optical imaging axis of image acquisition system 300. Preferably, image acquisition system 300 obtains an image of nozzle 210 prior to nozzle 210 picking component 304 from component feeder 14. Then, after component 304 has been picked by nozzle 210, image acquisition system 300 obtains a second, post-pick, image. A comparison of the before- and after-pick images provides important information relative to the effectiveness of the pick operation.

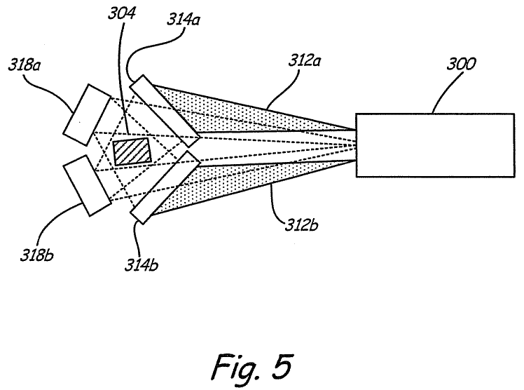

FIG. 5 is a top plan view of the system illustrated diagrammatically in FIG. 4, with nozzle 210 eliminated for ease of illustration. FIG. 5 illustrates image acquisition system 300 generating a pair of illumination beams 312A, 312B, which beams 312A, 312B impinge upon illumination optics 314A, 314B, respectively. Illumination optics 314A, 314B, redirect the illumination such that imaging optics 318A, 318B, provide backlit views of component 304 from two different points of view. The angular separation of the points of view is preferably 90 degrees. However, it is expressly contemplated that any suitable angular separation can be used, and that more than two points of view can be used in accordance with embodiments of the present invention. Image acquisition system 300 preferably acquires a single image having the plural points of view in a single imaging activity of system 300. Additionally, the configuration of optics 314A, 314B, and/or 318A, 318B may contain elements with or without optical power and elements used in transmission or reflection. These optics preferably redirect and condition illumination emanating from one or more illumination sources on system 300. However, embodiments of the present invention also expressly include sources of illumination that may not be disposed on or within system 300.

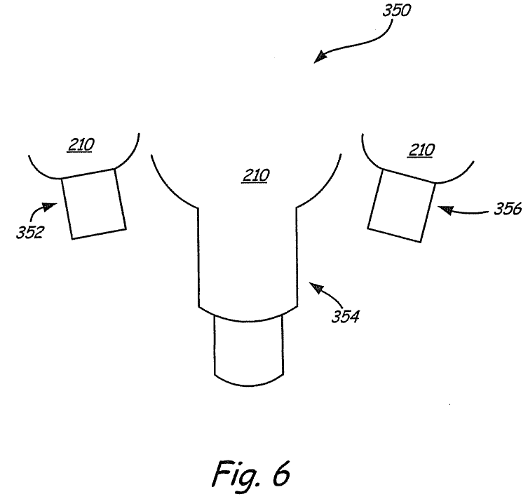

FIG. 6 is a diagrammatic view of an exemplary three-point-of-view before-pick image acquired in accordance with an embodiment of the present invention. Image 350 includes left image portion 352, center image portion 354, and right image portion 356. Each of image portions 352, 354, and 356 views nozzle 210 from a different angle. Additionally, FIG. 6 illustrates center image portion 354 having increased magnification in comparisons to left and right image portions 352, 356.

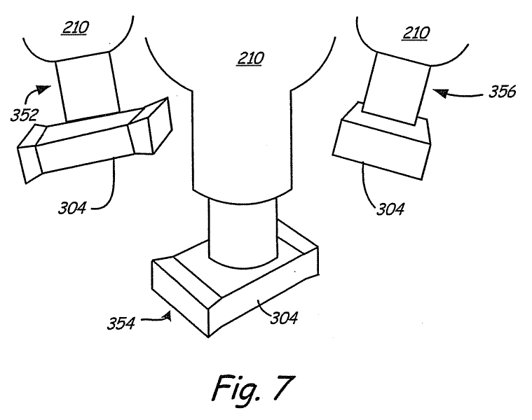

FIG. 7 is a diagrammatic exemplary view of the three-point-of-view embodiment illustrated in FIG. 6, but after a pick operation of component 304. As illustrated in FIG. 7, left image portion 352 illustrates component 304 in one orientation, while right image portion 356 illustrates component 304 from a different view. Further, center image portion 354 illustrates component 354 from a separate, intermediate, point of view. By comparing and/or contrasting the various images obtained from different points of view, important component pick information can be determined. Moreover, comparing and/or contrasting each after-pick image portion with its respective before-pick image portion to form a difference image easily isolates the image of the component while suppressing extraneous features. Then, comparing or contrasting the three difference images provides a relatively straightforward technique for generating pick efficacy information.

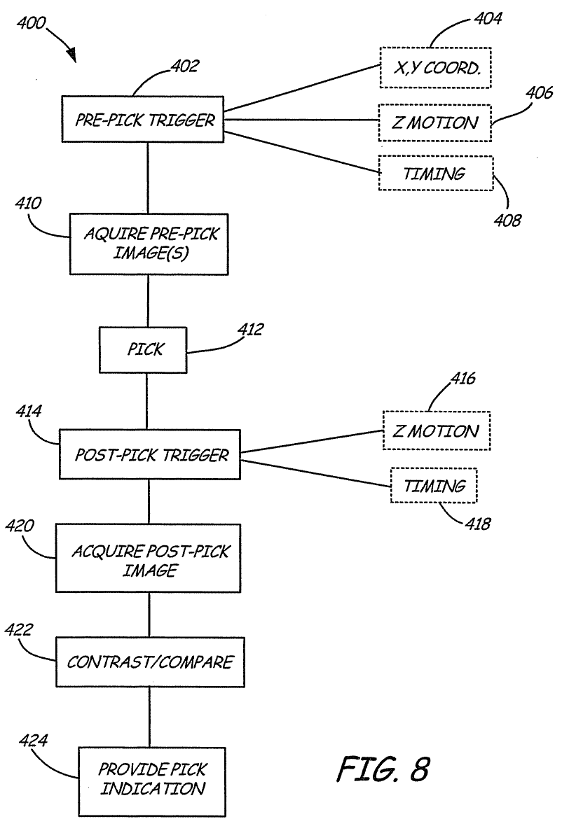

FIG. 8 is a flow diagram of a method 400 for acquiring multiple sets of images relative to a pick operation in an electronics assembly machine. Method 400 begins at step 402 where a pre-pick trigger is generated, or received. The pre-pick trigger can be provided in any suitable manner, by any suitable technique or device that is able to reliably signal a precise point in time prior to each pick operation. The trigger may be generated by monitoring the X, Y coordinates 404 provided by one or more encoders of the electronics assembly machine. Alternatively, or additionally, the pre-pick trigger can be generated by a particular Z motion 406 of the placement head or nozzle 210. Further still, the pre-pick trigger can be generated based, at least in part, upon timing functions 408. By communication of the position of nozzle 210 and component 304 from the mounter, or electronics assembly apparatus, through decoder signals, or other suitable signals, pre-pick trigger from step 402 causes image acquisition system 300 to acquire at least one pre-pick image having a plurality of image portions viewing the nozzle from different points of view, as indicated at block 410. As set forth above, the pre-pick image is preferably obtained during a single imaging operation of image acquisition system 300. The plurality of pre-pick image portions are arranged to view the nozzle from different points of view, preferably separated from 90 degrees. Next, at block 412, the assembly machine picks component 304 from component feeder 160. At block 414, a post-pick trigger is generated or obtained. The post-pick trigger can be generated as a function of Z-motion, such as the nozzle motion, 416, in the upward direction a certain distance, or the post-pick trigger can be a function of timing 418. For example, the post-pick trigger can be set to occur a precise time after component 304 has been picked. Once the post-pick trigger is generated, image acquisition system 300 acquires post-pick image having a plurality of image portions viewing the nozzle from different points of view, as indicated at block 420. The post-pick image portions are of substantially the same points of view as the pre-pick image portions. Moreover, the post-pick image portions are obtained via the same imaging optics and with the same image acquisition system as that of the pre-pick image. Thus, generating a difference image between a given pre-pick image portion and a respective post-pick image portion will easily isolate the picked component at the selected point of view. At block 422, the various images, preferably difference images, are contrasted and compared. The image analytics performed at block 422 results in a pick indication provided at block 424. Examples of suitable pick indications can be indications that no error or fault has occurred; that the picked component is fully tombstoned; that the picked component is partially tombstoned; that the picked component has a billboard condition; that the component has been picked up at one of its corners; or that the picked component is absent.

Embodiments of the present invention provide a number of advantages over the prior art. In particular, imaging is performed from at least two different vantage points that are preferably 90 degrees apart, so that an inconvenient orientation of the component can still be analyzed effectively. Further, data is acquired immediately after each pick operation so that the analyzed result is available well before placement of the picked component needs to occur. Further still, as set forth above, the same camera and illumination system can be used for pick evaluation and for placement evaluation.

Although the present invention has been described with reference to preferred embodiments, workers skilled in the art will recognize that changes may be made in form and detail without departing from the spirit and scope of the invention.

What is claimed is:

1. A pick and place machine for assembling a workpiece, the machine comprising:
a placement head having at least one nozzle for releasably picking up and holding the component;
a robotic system for generating relative movement between the placement head and the workpiece;
an image acquisition system disposed to obtain at least one before-pick image of a component pick up location and at least one after-pick image of the component pick up location;
an illuminator arranged to backlight the component with respect to the image acquisition system;
wherein the before-pick image contains a plurality of image portions, having each image portion view the pick-up location from a different point of view; and
wherein the after-pick image contains a plurality of image portions, having each image portion view the pick-up location from a different point of view.

2. The pick and place machine of claim 1, and further comprising illumination optics arranged to receive illumination from the illuminator and redirect the illumination proximate the component.

3. The pick and place machine of claim 2, and further comprising imaging optics arranged to focus a backlit image of the component upon the image acquisition system.

4. The pick and place machine of claim 1, and further comprising imaging optics arranged to focus a backlit image of the component upon the image acquisition system.
